(19) United States
(12) Patent Application Publication
(10) Pub. No.: US 2013/0328571 A1
(43) Pub. Date: Dec. 12, 2013

(54) Method And Device For Insulation Monitoring Comprising A Signal Quality Display

(71) Applicant: Bender GmbH & Co. KG, Gruenberg (DE)

(72) Inventors: Karl Schepp, Reiskirchen (DE); Tobias Groh, Muecke (DE)

(21) Appl. No.: 13/910,727

(22) Filed: Jun. 5, 2013

(30) Foreign Application Priority Data
Jun. 6, 2012 (DE) 10 2012 209 586.1

(51) Int. Cl. G01R 31/12

(52) U.S. Cl. CPC G01R 31/1272
USPC 324/551

(57) ABSTRACT

A method and to a device for insulation monitoring in ungrounded electrical direct or alternating current networks includes coupling in a measuring signal between active conductors of the network to be monitored and ground and registration of measured values of the measuring signal. The registered measured value of the measuring signal is determined in the form of a signal quality value which is displayed on a display.

### CROSS REFERENCE TO RELATED APPLICATION

This application claims the priority benefit of German Patent Application No. 10 2012 209 586.1 filed on Jun. 6, 2012, which is fully incorporated herein by reference.

### STATEMENT REGARDING FEDERALLY SPONSORED RESEARCH OR DEVELOPMENT

Not applicable.

### FIELD OF THE INVENTION

The invention relates to a method for insulation monitoring in ungrounded electrical direct or alternating current networks, comprising the method steps of coupling in a measuring signal between active conductors of the network to be monitored and ground and registering measured values of the measuring signal.

Further, the invention relates to a device for insulation monitoring in ungrounded electric direct or alternating current networks, comprising a coupling circuit for coupling in a measuring signal between active conductors of the network to be monitored and ground and for registering measured values of the measuring signal.

### BACKGROUND OF THE INVENTION

To ensure a high availability and operating security of the electric power supply and to guarantee personal safety in the area of electric installations, power supply networks are being increasingly employed whose active components are separated from the ground potential. In this type of power supply network, called ungrounded IT system (DIN VDE 0100-410):2007-06), an active conductor can have an insulation fault without the running operation having to be interrupted since due to the ideally infinitely high impedance value between the conductor and the ground in this first fault case no closed circuit can form. In this context, a faulty state of the IT system, in particular a fault to frame or an ground fault, meaning a conductive connection of inactive system parts to conductive operating parts or a conducting connection of an active conductor to the ground, are to be understood as an insulation fault.

It becomes clear from this point of view that the resistance in the network to be monitored, including all resistances of all connected operating parts to ground (insulation resistance), have to be monitored constantly because a possible further fault on another active conductor (second fault) could cause a fault loop and the fault current running therein in connection with an overcurrent protection circuit would result in a shut-down of the system. Through a constant insulation monitoring of the ungrounded IT system, a drop in the insulation resistance can be detected and reported in time. The requirements that have to be met by this kind of insulation monitoring devices are laid down in international standard IEC 61557-8.

According to the state of the art, the measuring processes for determining the insulation resistance are based in principle on the superposition of a measuring voltage (measuring signal), generated in an insulation monitoring device, between the conductors of the IT network and the ground so that a specific measuring current proportional to the insulation fault occurs, which causes a corresponding voltage drop (registered measured value of the measuring signal) on a measuring resistance of the insulation monitoring device. If the voltage drop exceeds a certain value as a result of a dropped insulation resistance and thus of a higher measuring current, a report is triggered. In order to prevent measurement distortions with regard to a reliable insulation monitoring in today's modern networks, in which a plurality of operating parts are equipped with electronic components, the distortions being caused for example by direct current components generated by inverters, the measuring methods have been continuously developed further. In pure alternating current networks without distorting direct current components, the method of superimposing a measuring DC voltage can be applied, whereas in faulty environments a controlled, specifically clocked measuring voltage for driving pulsed signals is employed.

For example, the publication EP 0 654 673 A1 describes a method for insulation monitoring in ungrounded direct and alternating current networks in which, while avoiding measuring value distortions, shorter measuring times are achieved by adapting the length of the individual pulses of the clocked alternating measuring voltage to the network conditions.

EP 1 586 910 B1 discloses a method and a device for insulation monitoring by means of a pulsed measuring voltage which is superimposed by a DC offset voltage so as to compensate for possibly present DC currents in the network distorting the measurement.

The patent specification DE 101 06 200 C1 shows a method and a device for insulation monitoring of ungrounded electrical networks in which for avoiding measuring errors, the measured value of an alternating pulse voltage variable in terms of value and duration is compared to a measuring current control value in a stable state, taking into account the time constant of the network.

In the afore-cited publications, a microprocessor is used for controlling the slow of the method and for making the calculations, an undershooting of a response value of the insulation resistance being reported optically and/or acoustically and the determined insulation resistance value being displayed on a displaying device. As recommended for example by DIN standard VDE 0100-410 (VDE 0100-410), “ first fault should be rectified as quickly as it is practically possible”. The system operator therefore wishes to obtain information as quickly and clearly as possible on the quality of the registered measured value of the measuring signal and on the values derived from it.

Apart from a display of the (absolute) values for the ohmic and capacitive part of the insulation resistance, a display of information relating to the polarity of the measuring pulses takes place, too, in document EP 1 586 910 A1 so that for example faults in certain branches can be recognized. Additionally, optical and/or acoustic alert reports are provided for specific fault situations. As displaying means, a moving coil instrument and also digital displaying forms are proposed therein.

Due to dynamic processes in the IT system, such as low-frequency voltages from frequency inverters or supply voltage fluctuations in PV installations, it is possible that erroneous alert reports, prolonged measuring times or a failure of the insulation resistance measurement occur in spite of the measuring method being adapted to the network conditions.

In particular in the case of so-called transient ground faults or briefly occurring insulation faults, it can be difficult for the system operator to correctly interpret the reports of the insulation monitoring device and to initiate suitable measures. Oftentimes, additional measurements or the assignment of maintenance workers is necessary to correctly assess the state of the IT system. In the worst case, a distorted measuring signal remains unnoticed and the IT system is operated without insulation monitoring.

So far, a detected distorted measuring signal—some insulation monitoring devices report measurement suppression through an optical signal—usually leads to an interruption of the insulation resistance measurement. Following an unreliable insulation fault report, the state of the IT system is often monitored manually with additional measuring devices so as to be able to make a diagnosis after a certain monitoring period. Oftentimes, specialists have to be assigned for maintenance in order to locate the insulation fault although the erroneous alert report was simply caused by a distorted measuring signal.

Starting from the state of the art, in addition to the alert reports and the display of the measured values, information would therefore be desirable which displays the momentary quality of the registered measured value of the measuring signal in a simple manner so as to allow an improved evaluation of the report of the insulation monitoring device. Further, a display showing the trend regarding the faulty conductor would be sensible, in particular in AC/DC or DC networks.

### SUMMARY OF THE INVENTION

It is therefore the object of the present invention to develop a method and a device for insulation monitoring in ungrounded electrical direct or alternating current networks which allow a quick and clear assessment of the reliability of the registered measuring signal (measured value of the measuring signal).

This object is attained with regard to a method in that a signal quality of the registered measured value of the measuring signal is determined in the form of a signal quality value and a display of the signal quality value is effected.

In addition to the alert reports and to the display of a determined insulation resistance value, according to the invention, at least one signal quality value in the sense of a reliability information is determined which allows a statement concerning the quality of the momentarily registered measured value of the measuring signal and thus enables the user to evaluate the measurement results. The thus determined signal quality value is represented in a display perceivable to the user so that the latter can evaluate the momentary measurement result with regard to its quality with the help of the displayed information. The improved assessment of the measuring accuracy makes a more successful and more efficient insulation fault search possible for the system operator and thus leads to cost savings by avoiding unnecessary maintenance assignments.

In an advantageous manner, the determination of the signal quality value is based on an evaluation of the temporal curve of the registered measured value of the measuring signal, wherein one or more of the following parameters are weightedly combined: statistical parameters of the registered measuring signal curve, the form of the registered measuring signal, outliers in the registered measuring signal curve, over/under-modulations, gain detection, temporal marginal conditions.

To be able to make a qualitative statement concerning the registered measuring signal, the temporal curve of the registered measuring signal is evaluated. Statistical parameters, such as the mean value, the variance of the measured value, outliers and over/under-modulations, are analyzed and weighted in particular and used to determine the signal quality value. Furthermore, gain detection and temporal marginal conditions, such as a measuring timeout, can be included in the determination of the signal quality value so as to achieve an even more accurate assessment of the quality of the registered measuring signal.

In a further realization, one or more of the following further parameters are advantageously weighted and included in the determination of the signal quality of the measuring signal: insulation resistance value, value of leakage capacity, supply voltage, supply frequency.

The insulation resistance value and the value of the leakage capacity as well as other network parameters and measured values, such as supply voltage and supply frequency, are included in the calculation of the signal quality value. Taking these additional values into account can further increase the validity of the assessment of the signal quality. Also, taking these further network parameters and measured values into account allows an optimization of the (adjustment) parameters of the insulation monitoring device and a choice of suitable measuring methods, if applicable also in connection with the choice of a better suited insulation monitoring device.

Preferably, alert values are saved together with the associated information on the signal quality of the measuring signal. In a history memory of this sort, older measured values, in particular older alert reports, can be stored with their corresponding signal quality values in order to be able to draw conclusions therefrom for a clearer evaluation of future events. This consideration of known correlations can also take place automated in the sense of a learning curve.

Advantageously, the display of the signal quality of the measuring signal is effected optically perceivable as a bar display and/or as a percentage in figures and/or as a multicolored LED display. To inform the user quickly and clearly about the signal quality, the momentary signal quality value is displayed by a bar display, which can be realized for example in the manner of a signal strength display in mobile radio devices as a multi-staged column diagram or in which the bar length corresponds to a specific signal quality value.

Apart from the option of an optical display, the display of the signal quality of the measuring signal can also be effected in an acoustically perceivable manner. Qualitatively reliable measured values can be signalized by a sound which is variable in volume and frequency.

Furthermore, for the signal quality value, a threshold value can be adjusted upon undercut of which an optically and/or acoustically perceivable report is effected and/or a switching output is activated. The user can determine manually that upon undercut of a specific signal quality value, a report is to be issued and thereby bring attention to the current network status. Apart from an optical and/or acoustic alert report, and undercut activates a switching output via which a signal can be output to other electrical components for their activation.

In a preferred realization of the invention, the faulty active conductor is determined and displayed. In case of a fault, when undershooting a certain insulation resistance value, the user thus is also informed in which of the active conductors of an IT system the insulation fault has likely occurred. Therein, the display of the faulty active conductor is preferably effected in an optically perceivable manner as a bar display or a column diagram with a trend indication and/or as a percentage in figures with a trend indication in the direction towards the most likely faulty active conductor.

The measuring signal is preferably coupled in as a pulsed alternating measuring voltage to prevent measurement distortions. By means of such measuring pulses that are adapted to network conditions, direct current components, for example generated by inverters, can in particular be counteracted.

The object on which the invention is based is further attained with regard to a device described herein by a computing unit for determining a signal quality value of the measured value of the measuring signal and a displaying means for displaying the determined signal quality value.

Corresponding to the method features of the method according to the invention, the device for insulation monitoring comprises a computing unit which executes the calculations, in particular the weighting and the suitable combination of the input signals, for determining the signal quality value. The computing unit is realized as a microprocessor on which the input signals are digitally processed in a program code and as a result, a signal quality value is rendered. The thus determined signal quality value is communicated according to the invention directly and in a comprehensible display to the user via an interface.

In further realization, the device comprises registering means for registering further electrical parameters characterizing the network. These parameters, such as the value of the leakage capacity, the supply voltage or the supply frequency, are used in the computing unit for determining the signal quality in order to be able to make a statement as accurate as possible about the quality and the reliability of the registered measured value of the measuring signal.

Further, the device comprises a data memory for recording the alert values together with the associated information on the signal quality of the measuring signal. This data memory can be used as a resource for making more reliable statements and assessments for future events by combining the alert value and the network conditions associated with said alert value.

Preferably, the displaying means for displaying the signal quality of the measuring signal is realized optically in the form of a bar display and/or as a percentage in figures and/or as a multicolored LED display. This kind of display allows the user a quick and clear grasp of the momentary signal quality of the measuring signal. Additionally, the displaying means for displaying the signal quality of the measuring signal can be realized acoustically in the form of a sound-generating means for making the user aware of critical network situations.

Furthermore, the device can comprise an adjusting device for adjusting a threshold value for the signal quality value. The adjusting device makes it possible that an undercut of the threshold value predetermined by the operator triggers an optical and/or acoustic report, a critical network status thus being clearly signalled. The optical signalling can be effected for example by separate displaying means or a blinking display of the displaying devices for the display of the signal quality. Acoustically, an undercut can be reported by an alert sound.

Further, the device can comprise a switching output, which is activated upon undercut of the threshold value for the signal quality value. Apart from an optically and/or acoustically perceivable display of the undercut of the threshold value, a switching output can thus be activated for the actuation of other connected electrical components by the adjusting device for adjusting a threshold value for the signal quality value.

In a preferred further embodiment, the device comprises additional displaying means for displaying the faulty active conductor in a DC or AC/DC network. From this display, which can also be realized as a trend display, it is visible to the user in the fault case which active conductor is most likely the faulty one.

The device advantageously comprises a generator circuit for generating a pulsed alternating measuring voltage as the measuring signal. This generator circuit makes it possible to generate measuring impulses that are adapted to the IT network so as to counteract possible distortions of the measured value caused by superimposed direct currents.

### BRIEF DESCRIPTION OF THE DRAWINGS

Further advantageous realization features result from the following description and the drawing showing a preferred embodiment of the invention in examples.

FIG. 1 shows a functional block diagram of the method according to the invention,

FIG. 2 shows a detailed illustration of the signal quality as a column diagram with percentages and

FIG. 3 shows a trend display for determining the faulty conductor.

### DETAILED DESCRIPTION OF THE EXAMPLE EMBODIMENTS

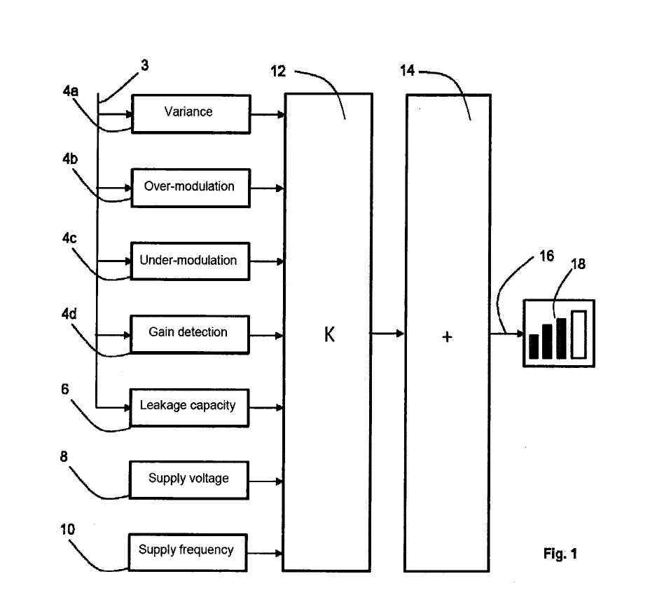

FIG. 1 shows a functional block diagram of the method according to the invention for determining the signal quality during insulation monitoring. The basic mode of action with exemplarily chosen data as input signals is illustrated.

The parameters variance 4a, over/under-modulation 4b/4c and gain detection 4d obtained from the temporal curve of the registered measured values 3 of the measuring signal, the leakage capacity 6 calculated from the registered measured value 3 of the measuring signal and the further network parameters supply voltage 8 and supply frequency 10 registered independently from the measured value 3 of the measuring signal are individually weighted 12 in a computing unit, preferably realized as a microprocessor, as input data provided in digital form and combined 14 with each other in a suitable manner. As a result of the digital signal processing 12, 14, a signal quality value 16 is determined and optically displayed in the form of a column diagram 18. Thus, it is directly visible to the user during the insulation resistance measurement how reliable the evaluations, in particular the registered insulation resistance value, are, which are based on the momentarily registered measured value 3 of the measuring signal.

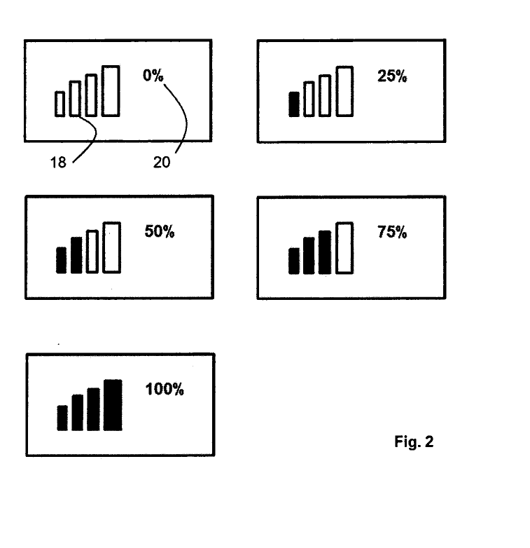

In FIG. 2, a detailed illustration of the signal quality in the form of a 4-stage column diagram 18 is visible at different signal quality levels. Additionally, the corresponding signal quality value 16 is displayed as a percentage 20, a display of four filled columns corresponding to a full signal quality (100%) of the registered measuring signal 3.

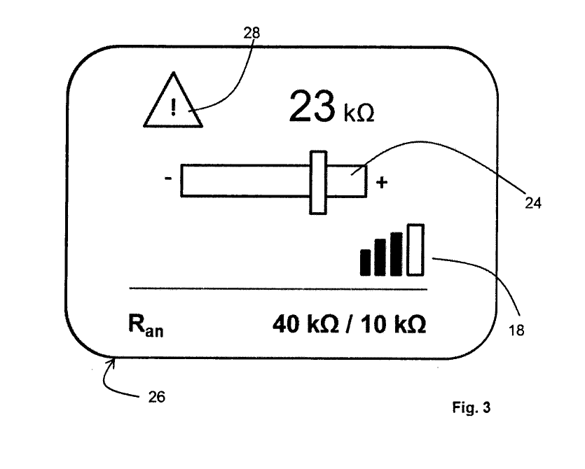

FIG. 3 shows a trend display 24 as a graphical illustration for determining a faulty active conductor in an AC/DC or DC IT network. The trend display 24 is part of a display 26 which additionally comprises a display of the signal quality value 16 as a column diagram 18 and further figure indications as information on the insulation resistance value and a warning symbol 28. It can be taken from the present example that as indicated by the warning symbol 28, an insulation fault has occurred, which can most likely be found in the +-conductor of the IT system since the trend display 24 trends in the direction of the positive conductor. The reliability of the measurement, meaning the quality of the measured data 3 of the measuring signal, is to be assessed as having a signal quality value of 75% according to the three filled columns of the column diagram 18.

1. A method for insulation monitoring in ungrounded electric direct or alternating current networks, said method comprising:
coupling a measuring signal between active conductors of a network to be monitored and ground;
registering measured values of the measuring signal;
determining a signal quality value of a signal quality of the registered measured values of the measuring signal; and
displaying the signal quality value on a display.

2. The method according to claim 1, in which determining the signal quality value is based on an evaluation of a temporal curve of the registered measured values of the measuring signal, said temporal curve being developed from at least one of the following parameters being weightedly combined: statistical parameters of the registered measuring signal curve, the form of the registered measuring signal, outliers in the registered measuring signal curve, under/over-modulations, gain detection, and temporal marginal conditions.

3. The method according to claim 1, in which at least one of the following further parameters are weightedly included in the determination of the signal quality of the measuring signal: insulation resistance value, value of the leakage capacity, supply voltage, and supply frequency.

4. The method according to claim 1, in which alert values are saved together with associated information on the signal quality of the measuring signal.

5. The method according to claim 1, in which the display of the signal quality of the measuring signal is effected in an optically perceivable manner as at least one of a bar display, a percentage in figures, and as a multicolored LED display.

6. The method according to claim 1, in which the display of the signal quality of the measuring signal is effected in an acoustically perceivable manner.

7. The method according to claim 1, in which for the signal quality value, a threshold value can be adjusted, upon undercut of which an optically and/or acoustically perceivable report is effected and/or a switching output is activated.

8. The method according to claim 1, in which a faulty active conductor is determined and displayed.

9. The method according to claim 8, in which the display of the faulty active conductor is effected in an optically perceivable manner.

10. The method according to claim 1, in which a pulsed alternating measuring voltage is coupled in as a measuring signal.

11. A device for insulation monitoring in ungrounded electric direct or alternating current networks, said device comprising:
a coupling circuit coupling in a measuring signal between active conductors of a network to be monitored and ground and registering measured values of the measuring signal;
a computing unit determining a signal quality value of the measured value of the measuring signal; and
a display displaying the determined signal quality value.

12. The device according to claim 11, including at least one register registering further electrical parameters characterizing the network.

13. The device according to claim 11, including a data memory recording alert values together with associated information on the signal quality of the measuring signal.

14. The device according to claim 11, in which the display displaying the signal quality of the measuring signal optically displays the signal quality of the measuring signal in the form of at least one of a bar display, a percentage in figures, and a multicolored LED display.

15. The device according to claim 11, in which the display displaying the signal quality of the measuring signal is realized acoustically.

16. The device according to claim 11, including an adjusting device adjusting a threshold value for the signal quality value.

17. The device according to claim 16, including a switching output, which is activated upon undercut of the threshold value for the signal quality value.

18. The device according to claim 11, including a further display for the rendition of a faulty active conductor in a network.

19. The device according to claim 11, including a generator circuit generating a pulsed alternating measuring voltage as a measuring signal.

20. The method according to claim 9, in which the display of the faulty active conductor is effected in an optically perceivable manner as at least one of a bar display, a column diagram with a trend indication, and a percentage in figures with a trend indication.
